(19) United States
(12) Patent Application Publication
(10) Pub. No.: US 2019/0391208 A1
(43) Pub. Date: Dec. 26, 2019

(54) BATTERY MODULE

(71) Applicant: HONDA MOTOR CO., LTD., Tokyo (JP)

(72) Inventors: Kazuhisa IN, Saitama (JP); Hiroki ITAYA, Saitama (JP); Atsushi NAKANO, Saitama (JP)

(73) Assignee: HONDA MOTOR CO., LTD., Tokyo (JP)

(21) Appl. No.: 16/432,011

(22) Filed: Jun. 5, 2019

(30) Foreign Application Priority Data
Jun. 22, 2018 (JP) 2018-119104

(51) Int. Cl. G01R 31/364; H01M 10/48; H01M 2/10

(52) U.S. Cl. CPC G01R 31/364; H01M 10/48; H01M 2220/20; H01M 2/1077; H01M 2/1083

(57) ABSTRACT

A battery module includes: a cell-stacked body constituted by stacking a plurality of cells; and a sensor device configured to detect a voltage of each cell. The sensor device is disposed on an upper surface of the cell-stacked body. An insulation plate is provided between adjacent cells, and the sensor device is vertically fixed to at least two insulation plates spaced in a stacking direction.

### CROSS-REFERENCE TO RELATED APPLICATION(S)

This application claims priority from Japanese Patent Application No. 2018-119104 tiled on Jun. 22, 2018, the entire contents of which are incorporated herein by reference.

### FIELD

The present invention relates to a battery module mounted on an electric vehicle or the like.

### BACKGROUND

In a related art, a battery module is mounted on an electric vehicle and the like. For example, JP-A-2016-072181 discloses a battery module including a cell-stacked body constituted by stacking a plurality of cells and a sensor device which detects the voltage of each cell.

In recent years, in this type of battery module, the capacity of a battery is increased and it becomes impossible to ignore dimensional expansion caused by the expansion of a cell due to temperature change and aged deterioration. Therefore, it is difficult to fix the sensor device firmly on an upper surface of a cell-stacked body at two or more points, and there is a risk that the sensor device may rattle due to vibration when a vehicle travels.

The invention provides a battery module capable of preventing rattling of a sensor device while the sensor device is disposed on an upper surface of a cell-stacked body.

### SUMMARY

A battery module according to the invention, includes:

a cell-stacked body constituted by stacking a plurality of cells; and

a sensor device configured to detect a voltage of each cell, in which

the sensor device is disposed on an upper surface of the cell-stacked body,

an insulation plate is provided between adjacent cells, and

the sensor device is vertically fixed to at east two insulation plates spaced in a stacking direction.

According to the invention, since the sensor device is vertically fixed to the at least two insulation plates spaced in the stacking direction, the rattling of the sensor device can be prevented while the sensor device is disposed on the upper surface of the cell-stacked body in the battery module.

### BRIEF DESCRIPTION OF DRAWINGS

FIG. 1 is a perspective view of a battery module according to an embodiment of the invention as viewed obliquely from above.

FIG. 2 is an exploded perspective view of the battery module of FIG. 1.

FIG. 3 is a plan view of the battery module of FIG. 1,

FIG. 4 is a perspective view of a sensor device of the battery module of FIG. 1 as viewed obliquely from below.

FIG. 5 is a cross-sectional view taken along the line A-A of FIG. 4.

FIG. 6 is an enlarged perspective view of an essential part of the battery module of FIG. 1 as viewed obliquely from above.

FIG. 7 is a cross-sectional view taken along the line B-B of FIG. 6.

### DETAILED DESCRIPTION

Hereinafter, each embodiment of a battery module of the invention will be described based on the accompanying drawings. The drawings should be viewed in the direction of reference signs.

### [Battery Module]

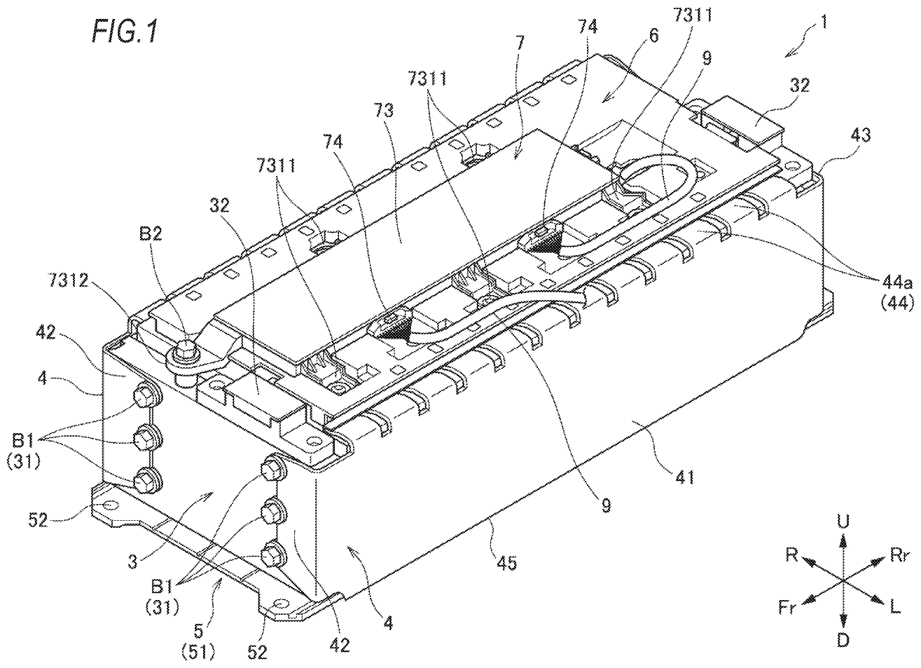

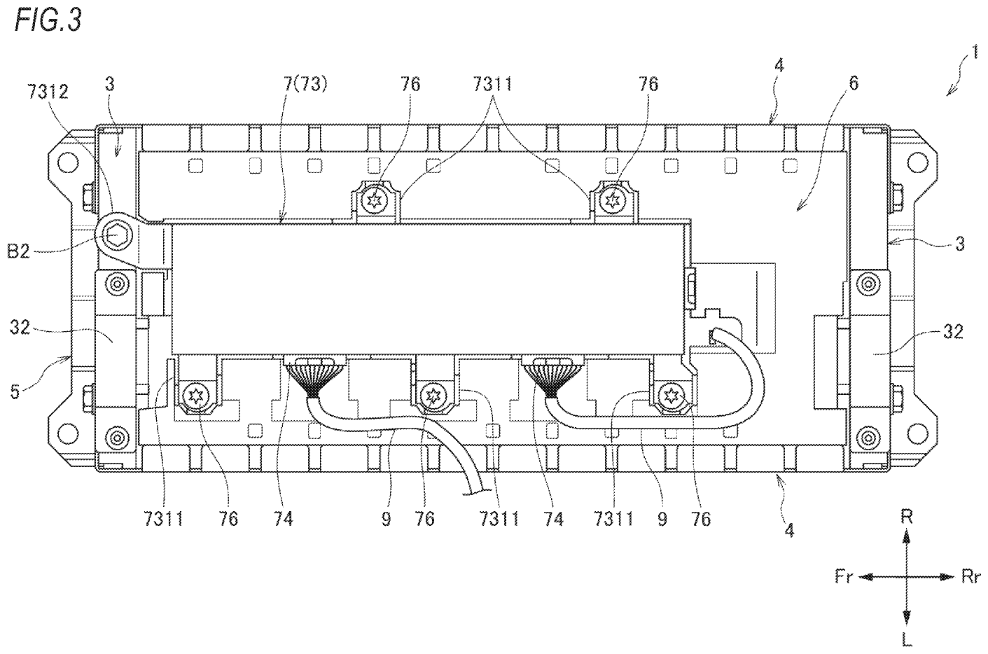

As illustrated in FIGS. 1 to 3, a battery module 1 according to the embodiment includes a cell-stacked body 2 configured by stacking a plurality of cells 21 in a front-rear direction and having a front surface, a rear surface, a left surface, a right surface, an upper surface, and a lower surface; a pair of end plates 3 disposed on the front surface and the rear surface of the cell-stacked body 2; a pair of side frames 4 disposed on the left surface and the right surface of the cell-stacked body 2 and connecting the pair of end plates 3; a lower plate 5 disposed under the lower surface of the cell-stacked body 2; a sensor device 7 disposed on the upper surface of the cell-stacked body 2 for detecting the voltage of each cell 21; and a top cover 6 covering a region of the top surface of the cell-stacked body 2 on which the sensor device 7 is not mounted.

In this specification and the like, in order to simplify and clarify the description, a stacking direction of the cells 21 is defined as a front-rear direction and directions perpendicular to the stacking direction of the cells 21 are defined as a right-left direction (width direction) and an up-down direction (height direction) and those directions are irrelevant to the front-rear direction and the like of a product on which the battery module 1 is mounted. That is, when the battery module 1 is mounted on a vehicle, the stacking direction of the cells 21 may match the front-rear direction of the vehicle, or may be the up-down direction or the right-left direction of the vehicle, or may be a direction inclined from those directions. In the drawings, the front of the battery module 1 is indicated as Fr, the rear is indicated as Rr, the left side is indicated as L, the right side is indicated as R, the upper side is indicated as U, and the lower side is indicated as D.

### (Cell-Stacked Body)

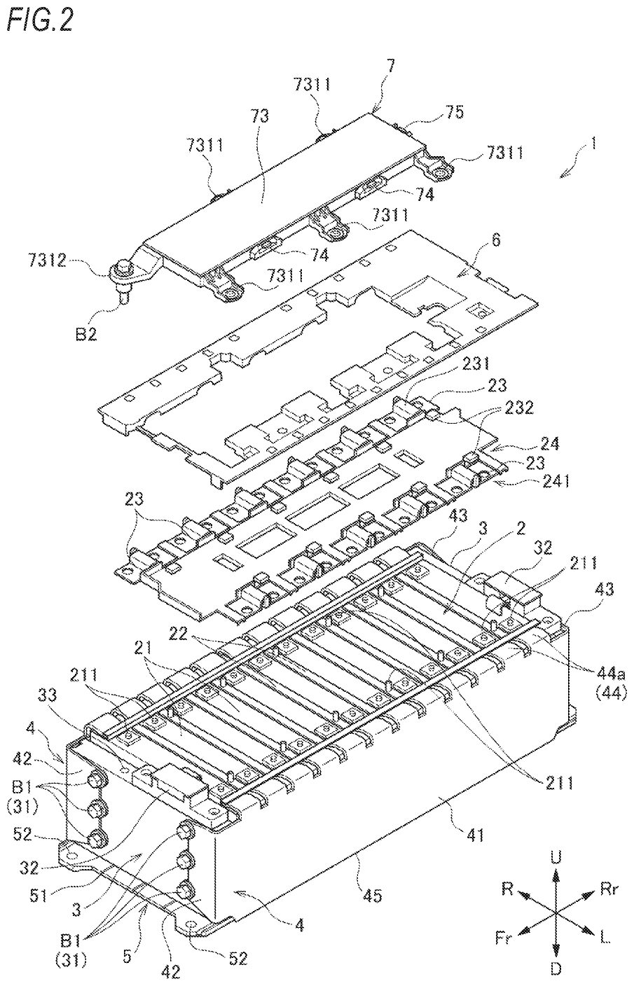

As illustrated in FIG. 2, the cell-stacked body 2 is constituted by alternately stacking a plurality of cells 21 and a plurality of insulation plates 22 in the front-rear direction. A plurality of bus bars 23 electrically connected to terminals 211 of the cells 21 are disposed on the upper surface of the cell-stacked body 2. The plurality of bus bars 23 connect the terminals 211 of the adjacent cells 21 so that the plurality of cells 21 are electrically connected in series. Specifically, the plurality of cells 21 are stacked such that the terminal 211 on a positive side and the terminal 211 on a negative side are sequentially reversed horizontally, and the plurality of bus bars 23 sequentially connect the terminals 211 on the positive side (or negative side) of the cell 21 adjacent to an upper side in the cell stacking direction and the terminals 211 on the negative side (or positive side) of the cell 21 adjacent to a lower side in the cell stacking direction. Accordingly, the plurality of bus bars 23 electrically connect the plurality of cells 21 in series.

A bus bar plate 24 for holding the plurality of bus bars 23 is provided on the upper surface of the cell-stacked body 2. The bus bar plate 24 includes a plurality of bus bar holders 241. When the bus bar plate 24 is placed on the upper surface of the cell-stacked body 2 after holding the plurality of bus bars 23 in the bus bar holders 241, the plurality of bus bars 23 are positioned at predetermined locations connectable to the corresponding terminals 211. Also, the bus bar plate 24 of the embodiment is not a jig which is detached after connecting the bus bars 23 to the terminals 211, but a constituent element of the battery module 1, which maintains a mounted state thereof even after connecting the bus bars 23 to the terminals 211.

The cell 21 is known to expand due to temperature change and aged deterioration. The cell 21 has a rectangular shape in which the length in the up-down direction is longer than that in the front-rear direction and the length in the right-left direction is longer than that in the up-down direction. Therefore, the areas of the front and rear surfaces of the cell 21 are much larger than the areas of the left, right, upper, and lower surfaces, and thus the central portion in the right-left direction and the central portion in the up-down direction of the front and rear surfaces of the cell 21 easily expand. When the cell 21 expands in the front-rear direction, stress acts on the bus bar 23 connecting the terminals 211 of the cells 21 to each other. The bus bar 23 of the embodiment includes a bent portion 231 protruding upward at the middle portion in the front-rear direction in order to relieve the stress acting as the cell 21 expands.

### (End Plate)

As illustrated in FIGS. 1 to 3, the pair of end plates 3 are arranged along the front surface and the rear surface of the cell-stacked body 2 and receive a load of the cell-stacked body 2 in the cell stacking direction due to the expansion of the cell 21. The end plate 3 of the embodiment is formed using an aluminum extrusion material and a plurality of fastening portions 31 to be fastened to side frames 4 with bolts B1 are provided at the left and right end portions of an outer surface not facing the cell-stacked body 2. In addition, on the upper surface of the pair of end plates 3, there are provided external connection terminal bases 32 for transferring and receiving power between the battery module 1 and an external electric device, and further a sensor fixing portion 33 to which the sensor device 7 is fixed via a bolt B2 is provided on the upper surface of one of the end plates 3.

### (Side Frame)

As illustrated in FIGS. 1 to 3, the side frames 4 are formed by pressing a metal plate material and includes side frame main bodies 41 along the left or right surface of the cell-stacked body 2, front flange portions 42 extending from front ends of the side frame main bodies 41 in a direction approaching each other along the front surface of the end plate 3 on the front side, rear flange portions 43 extending from rear ends of the side frame main bodies 41 in a direction approaching each other along the rear surface of the end plate 3 on the rear side, upper flange portions 44 extending from upper ends of the side frame main bodies 41 in a direction approaching each other along the upper surface of the cell-stacked body 2, and lower flange portions 45 extending from lower ends of the side frame main bodies 41 in a direction approaching each other along the lower surface of the cell-stacked body 2 (lower plate 5).

The front flange portions 42 and the rear flange portions 43 are fastened to the end plate 3 on the front side and the end plate 3 on the rear side through the bolts 131. Therefore, the pair of end plates 3 are connected via the pair of side frames 4. The pair of side frames 4 allow relative displacement in the front-rear direction of the end plates 3 when the load of the cell-stacked body 2 in the cell stacking direction increases. For example, the relative displacement of the end plates 3 in the front-rear direction is allowed by the deformation of the side frame main bodies 41 in the front-rear direction, the angle change of the side frame main bodies 41 and the front flange portions 42 or the rear flange portions 43, and the like.

The upper flange portions 44 and the lower flange portions 45 vertically pinch the cell-stacked body 2 and the lower plate 5 at the left end portion and the right end portion of the cell-stacked body 2. Therefore, the relative positional fluctuation of the cell-stacked body 2, the side frames 4, and the lower plate 5 in the up-down direction is restricted and the plurality of cells 21 constituting the cell-stacked body 2 can be aligned.

The upper flange portion 44 of the embodiment is constituted of a plurality of elastic pieces 44a aligned in the front-rear direction and the number and positions of the elastic pieces 44a correspond to the number and positions of the cells 21 stacked in the front-rear direction. As a result, the upper flange portion 44 can elastically hold the plurality of cells 21 individually with appropriate elasticity. The lower flange portion 45 is fixed to or engaged with the lower plate 5 via fastened portions (not illustrated).

### (Lower Plate)

As illustrated in FIGS. 1 and 2, the lower plate 5 is formed using an aluminum extrusion material and includes a lower plate main body 51 extending along the lower surfaces of the cell-stacked body 2 and end plates 3, a plurality of fixing portions 52 to be fixed to a module support structure (not illustrated) supporting the battery module 1, and fastening portions (not illustrated) to which the lower flange portions 45 of the side frames 4 are fastened.

### (Sensor Device)

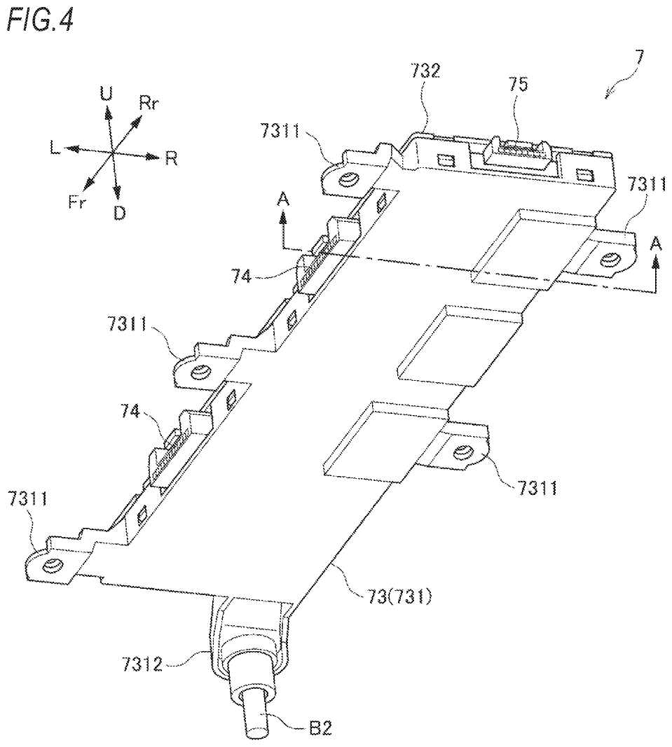

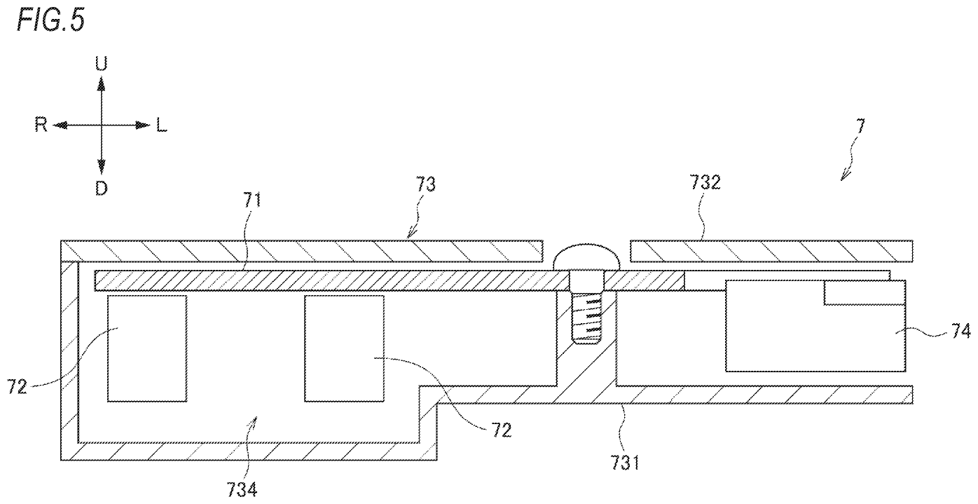

As illustrated in FIGS. 4 and 5, the sensor device 7 includes a substrate 71, an electronic component 72 mounted on the substrate 71, and a case 73 for accommodating the substrate 71 and the electronic component 72, voltage detection connectors 74 disposed on the side surfaces of the case 73, a detection signal output connector 75. Further, the sensor device 7 of the embodiment is provided with two voltage detection connectors 74 in order to enable voltage detection of two battery modules 1. However, the number of voltage detection connectors 74 may be one or three or more.

The substrate 71 in the embodiment is a print substrate having a rectangular shape in plan view which is long in the front-rear direction. In the substrate 71, the wiring is printed on the upper surface and the electronic component 72, the voltage detection connector 74, and the detection signal output connector 75 are mounted on the lower surface.

The case 73 includes a case main body 731 which covers a lower surface side of the substrate 71 and a lid case 732 which covers an upper surface side of the substrate 71. The case main body 731 includes a plurality of first fixing portions 7311 and one second fixing portion 7312 and is fixed to the upper surface of the cell-stacked body 2 via the fixing portions 7311 and 7312. The specific fixing structure of the first fixing portion 7311 and the second fixing portion 7312 to the upper surface of the cell-stacked body 2 will be described below.

The voltage detection connector 74 is connected to each bus bar 23 via a plurality of voltage detection lines 9. One end sides of the plurality of voltage detection lines 9 are connected to the voltage detection connector 74 of the sensor device 7 through the cable-side connector. Further, the other end sides of the plurality of voltage detection lines 9 are connected to respective bus bars 23 via a space secured between the upper surface of the cell-stacked body 2 and the lower surface of the sensor device 7.

One end side of a detection signal output line (not illustrated) is connected to the detection signal output connector 75. The other end side of the detection signal output line is connected to a charge and discharge control unit (not illustrated) of a vehicle and the voltage detection signal of each cell 21 output from the sensor device 7 is input to the charge and discharge control unit of a vehicle via the detection signal output line.

### (Fixing Structure of Sensor Device)

Next, a specific fixing structure of the sensor device 7 to the cell-stacked body 2 will be described.

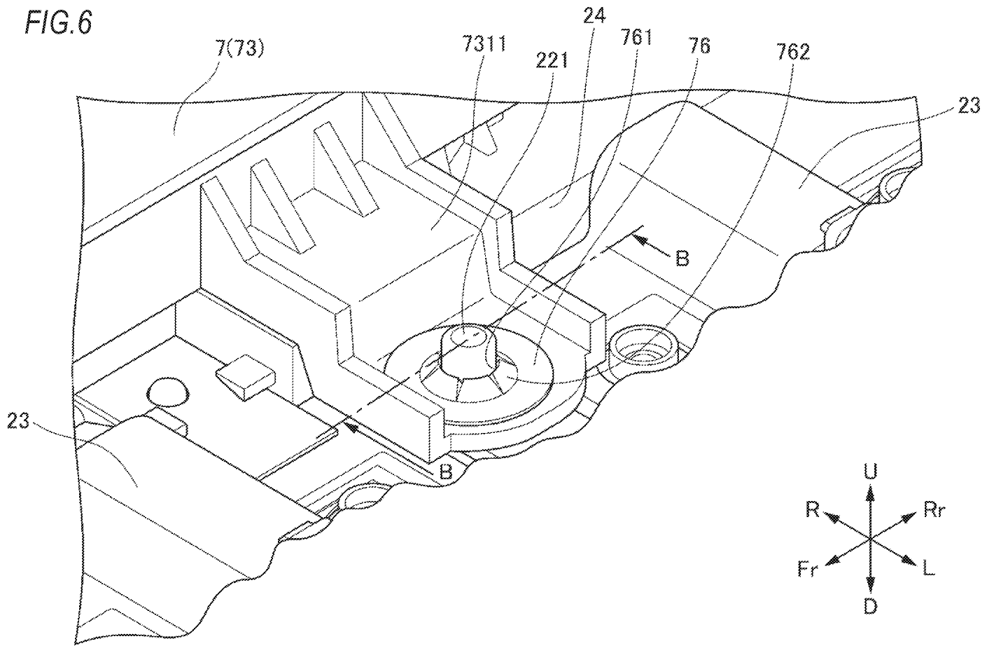

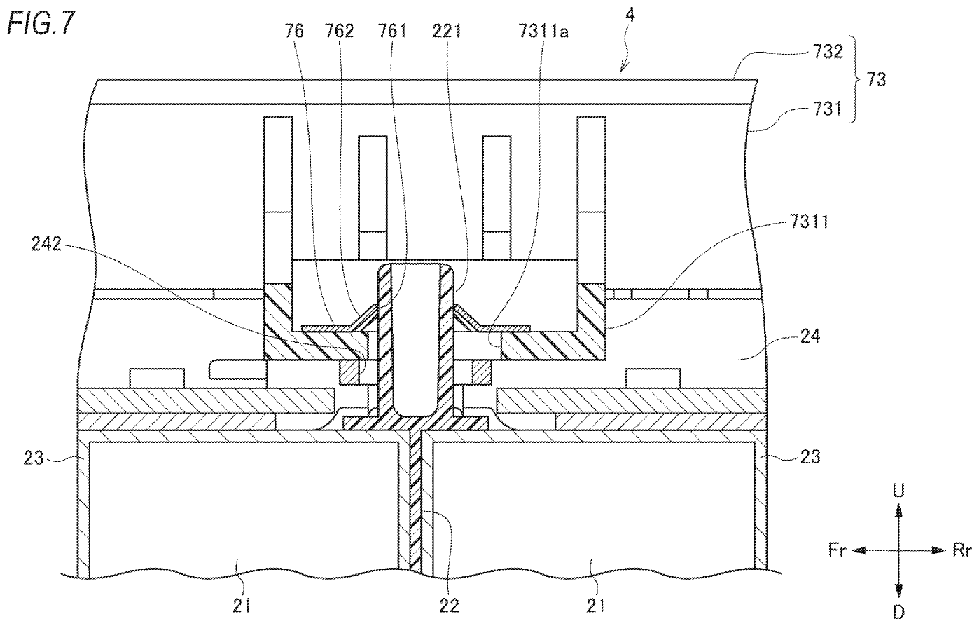

As illustrated in FIGS. 1 to 4, a plurality of first fixing portions 7311 described above are provided on the left side and the right side of the case main body 731 at predetermined intervals in the front-rear direction. The first fixing portions 7311 are fixed to the plurality of insulation plates 22 spaced in the front-rear direction in an immovable way in the up-down direction and in a movable way in the front-rear direction. Specifically, as illustrated in FIGS. 6 and 7, the insulation plate 22 includes a cylindrical protrusion portion 221 protruding upward and the first fixing portion 7311 includes a hole 7311a for accommodating the protrusion portion 221 in a state where the protrusion portion 221 is inserted into the hole 7311a from below. The hole 7311a is a long hole which is long in the front-rear direction and can allow relative movement between the insulation plate 22 and the sensor device 7 in the front-rear direction as the cell 21 expands.

As illustrated in FIGS. 6 and 7, the first fixing portion 7311 of the case main body 731 is inserted from above into the protrusion portion 221 of the insulation plate 22. Then the first fixing portion 7311 is fixed in the up-down direction by a push nut 76 to be attached to the protrusion portion 221 by press-fitting from above. The push nut 76 includes a plurality of claw portions 762 inclined upward at a peripheral edge portion of the hole 761 formed in the central portion. When the push nut 76 is press-fitted into the protrusion portion 221 from above, the plurality of claw portions 762 bite into the outer peripheral portion of the protrusion portion 221, whereby the upward removal of the push nut 76 is restricted. Therefore, the first fixing portion 7311 of the case main body 731 is vertically fixed to the protrusion portion 221 of the insulation plate 22 through the push nut 76 and the first fixing portion 7311 is allowed to move back and forth relative to the protrusion portion 221 of the insulation plate 22 by the hole 7311a which is a long hole.

In the battery module 1 of the present embodiment, the protrusion portions 221 of the insulation plates 22 and the push nuts 76 are also used as fixing portions and fixing members of the bus bar plate 24. Specifically, the bus bar plate 24 includes a plurality of holes 242 to which the protrusion portions 221 of the insulation plates 22 are inserted and is interposed between the first fixing portions 7311 of the case main body 731 to which the protrusion portions 221 of the insulation plates 22 are inserted and the upper surfaces of the cells 21. Further, the bus bar plate 24 is vertically fixed to the protrusion portions 221 of the insulation plates 22 via the first fixing portions 7311 and the push nuts 76.

The second fixing portion 7312 described above is provided in a protruding manner at one end portion (in this embodiment, the front end portion) of the case main body 731 in the front-rear direction and is fixed to the sensor fixing portion 33 provided on one of the front and rear end plates 3 via the bolt B2 in an immovable way in the front-rear direction and the up-down direction. Therefore, since the sensor device 7 is vertically fixed by the plurality of first fixing portions 7311 and one second fixing portion 7312, the vertical rattling of the sensor device 7 due to vibration when a vehicle travels is restricted. In addition, since the sensor device 7 is fixed in the front-rear direction by one second fixing portion 7312, not only rattling in the front-rear direction due to vibration when a vehicle travels is restricted, but also the stress can be prevented from being generated in the sensor device 7 due to the expansion of the cells 21.

In the embodiment described above, modifications, improvements, and the like can be made as appropriate. For example, in the sensor device 7 of the embodiment described above, the first fixing portions 7311 and the second fixing portion 7312 are provided in the case 73 which accommodates the substrate 71 and those fixing portions 7311 and 7312 are fixed to the cell-stacked body 2. However, in a battery module in which the case is not provided and the substrate is fixed to the cell-stacked body in a state where the substrate is exposed, holes corresponding to the first fixing portions and the second fixing portion of the embodiment are provided in the substrate and those holes can be fixed to the cell-stacked body 2 with the same fixing structure as the first fixing portions and the second fixing portion of the embodiment.

### SUMMARY

At least the following matters are described in the description. In addition, the constituent components or the like corresponding to the embodiment described above are described in parenthesis, but are not limited thereto.

(1) A battery module (battery module 1) including:

a cell-stacked body (cell-stacked body 2) constituted by stacking a plurality of cells (cells 21); and

a sensor device (sensor device 7) configured to detect a voltage of each cell, in which

the sensor device is disposed on an upper surface of the cell-stacked body,

an insulation plate (insulation plate 22) is provided between adjacent cells, and

the sensor device is vertically fixed to at least two insulation plates spaced in a stacking direction.

According to (1), since the sensor device is vertically fixed to the at least two insulation plates spaced in the stacking direction, the rattling of the sensor device can be prevented while the sensor device is disposed on the upper surface of the cell-stacked body in the battery module.

(2) The battery module according to (1), in which

the sensor device includes:
a substrate (substrate 71);
an electronic component (electronic component 72) mounted on the substrate, and
a case (case 73) accommodating the substrate and the electronic component, and

the case includes fixing portions (first fixing portion 7311) fixed to the at least two insulation plates.

According to (2), since the substrate and the electronic component are accommodated in the case, the substrate and the like are protected by the case. Further the sensor device can be fixed to the insulation plates by the fixing portions provided in the case.

(3) The battery module according to (1), in which

the sensor device includes:
substrate (substrate 71); and
an electronic component (electronic component 72) mounted on the substrate, and

the substrate includes fixing portions fixed to the at least two insulation plates.

According to (3), the sensor device can be fixed to the insulation plates by the fixing portions provided in the substrate While reducing the number of parts of the sensor device.

(4) The battery module according to any one of (1) to (3), in which

the insulation plate includes a protrusion portion (protrusion portion 221) protruding upward, and

the sensor device includes fixing portions (first fixing portion 7311), each of which is a hole (hole 7311a) for accommodating the protrusion portion.

According to (4), since the fixing portions each is engaged with the protrusion portion of the insulation plate, the movement of the sensor device in the stacking direction is restricted in addition to the up-down direction.

(5) The battery module according to (4), in which

the hole is a long hole which is long in the stacking direction.

According to (5), relative movement of the insulation plate and the sensor device in the cell stacking direction can be allowed as the cell expands.

(6) The battery module according to (5), in which

a pair of end plates (end plates 3) is provided at both end portions of the cell-stacked body in the stacking direction, and

the sensor device is fixed to one end plate of the pair of end plates in an immovable way in the stacking direction.

According to (6), while the sensor device is positioned in the stacking direction with respect to the one end plate, relative movement is allowed in the stacking direction with respect to the cell-stacked body.

(7) The battery module according to (5) or (6), in which

the sensor device is fixed by a push nut (push nut 76) in a state where the protrusion portion provided in the insulation plate is inserted into the fixing portion.

According to (7), movement of the sensor device in the stacking direction is allowed while the rattling in the up-down direction is restricted by the push nut.

1. A battery module comprising:
a cell-stacked body constituted by stacking a plurality of cells; and
a sensor device configured to detect a voltage of each cell, wherein
the sensor device is disposed on an upper surface of the cell-stacked body,
an insulation plate is provided between adjacent cells, and
the sensor device is vertically fixed to at least two insulation plates spaced in a stacking direction.

2. The battery module according to claim 1, wherein
the sensor device includes:
a substrate;
an electronic component mounted on the substrate, and
a case accommodating the substrate and the electronic component, and
the case includes fixing portions fixed to the at least two insulation plates.

3. The battery module according to claim 1, wherein
the sensor device includes:
a substrate; and
an electronic component mounted on the substrate, and
the substrate includes fixing portions fixed to the at least two insulation plates.

4. The battery module according to claim 1, wherein
the insulation plate includes a protrusion portion protruding upward, and
the sensor device includes fixing portions, each of which is a hole for accommodating the protrusion portion.

5. The battery module according to claim 4, wherein
the hole is a long hole which is long in the stacking direction.

6. The battery module according to claim 5, wherein
a pair of end plates is provided at both end portions of the cell-stacked body in the stacking direction, and
the sensor device is fixed to one end plate of the pair of end plates in an immovable way in the stacking direction.

7. The battery module according to claim 5, wherein
the sensor device is fixed by a push nut in a state where the protrusion portion provided in the insulation plate is inserted into the fixing portion.
